(19) United States
(12) Patent Application Publication
(10) Pub. No.: US 2024/0260237 A1
(43) Pub. Date: Aug. 1, 2024

(54) SEMICONDUCTOR STORAGE DEVICE INCLUDING PCB EDGE HEAT DISSIPATION

(71) Applicant: Western Digital Technologies, Inc., San Jose, CA (US)

(72) Inventors: Wei Hong Tew, Penang (MY); Chun Sean Lau, Penang (MY); Tze Ping Chan, Penang (MY)

(73) Assignee: Western Digital Technologies, Inc., San Jose, CA (US)

(21) Appl. No.: 18/222,776

(22) Filed: Jul. 17, 2023

Related U.S. Application Data
(60) Provisional application No. 63/441,614, filed on Jan. 27, 2023.

(51) Int. Cl. H05K 7/20; H05K 1/02; H05K 1/18; H05K 3/00

(52) U.S. Cl. CPC H05K 7/205; H05K 1/0206; H05K 1/181; H05K 3/0052; H05K 7/20463; H01L 25/18; H05K 3/3436; H05K 2201/10159; H05K 2201/10378; H05K 2201/10515; H05K 2201/10522; H05K 2201/10734; H10B 80/00

(57) ABSTRACT

A semiconductor storage device includes semiconductor packages mounted on a printed circuit board (PCB) and encased within an enclosure. The semiconductor storage device includes thermal interface material mounted on side edges of the PCB. During depaneling (separation) of individual semiconductor storage devices from a PCB panel, edges of the PCB may be overcut to expose thermally conductive edge layers provided within the interior the PCB. The thermal interface material may be positioned adjacent to the exposed thermally conductive edge layers to conduct heat away from a semiconductor package through the side edges of the PCB and out of sides of the enclosure.

### CLAIM OF PRIORITY

The present application claims priority from U.S. Provisional Patent Application No. 63/441,614, entitled “SEMICONDUCTOR STORAGE DEVICE INCLUDING PCB EDGE HEAT DISSIPATION,” filed Jan. 27, 2023, which is incorporated by reference herein in its entirety.

### BACKGROUND

The strong growth in demand for portable consumer electronics is driving the need for high-capacity storage devices. Non-volatile semiconductor memory devices are widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computers, cellular telephones and SSD (solid state drives).

While many varied packaging configurations are known, flash memory semiconductor packages may in general be assembled as system-in-a-package (SIP), where a controller die and a number of memory dies are mounted and interconnected to an upper surface of substrate such as a printed circuit board. Electrical connections are formed between the dies and the substrate. In a so-called BGA (ball grid array package), solder balls may be mounted on a bottom surface of the SiP memory for electrically and physically coupling the SiP memory to the printed circuit board. It is advantageous to mount additional SiP memory packages to the substrate to increase or maximize storage capacity.

Current generation SiP memory packages are formed using 3D NAND, such as 3D BiCS (Bit Cost Scaling) and V-NAND. Such memories offer increased storage capacity as compared to prior generation memory packages, but 3D SiP memory packages are generally thicker than prior generation memory packages. Moreover, in the rapid evolution of 3D NAND technologies, Z-dimension/package thickness has become important to allow more layers to be stacked within a package. Also, it is known to mount a SiP memory package in an enclosure with a thermal interface material (TIM) on a top surface of the SiP memory package to conduct heat away from the package during operation. A problem arises in the use of 3D SiP memory packages in that the height of these packages prevents the inclusion of a TIM on an upper surface of the package while still fitting within the standard form factor of the enclosure.

### DESCRIPTION OF THE DRAWINGS

FIG. 1 is a flowchart of the overall assembly process of semiconductor package according to embodiments of the present technology.

FIG. 2 is a side view of a semiconductor package during assembly according to an embodiment of the present technology.

FIG. 3 is a top view of a semiconductor package during assembly according to an embodiment of the present technology.

FIG. 4 is a bottom view of a semiconductor package during assembly according to an embodiment of the present technology.

FIG. 5 is an edge view of a completed semiconductor package according to embodiments of the present technology.

FIG. 6 is a top view of a printed circuit board panel according to embodiments of the present technology.

FIG. 7 is a cross-sectional view through line 7-7 of FIG. 6 showing interior layers of a printed circuit board according to embodiments of the present technology.

FIG. 8 is a top view of a printed circuit board panel including a number of semiconductor storage devices during assembly according to embodiments of the present technology.

FIG. 9 is a cross-sectional view through line 9-9 of FIG. 8 showing an interior of a semiconductor storage device during assembly.

FIG. 10 is a top view of a printed circuit board panel including a number of semiconductor storage devices during assembly with the routing tabs shown in dashed lines.

FIG. 11 is a cross-sectional view through line 11-11 of FIG. 10 showing an interior of a semiconductor storage device during assembly with the routing tabs shown in dashed lines.

FIG. 12 is a top view of a printed circuit board panel including a number of semiconductor storage devices during assembly with the routing tabs removed to depanel individual semiconductor storage devices.

FIG. 13 is a cross-sectional view through line 13-13 of FIG. 12 showing an interior of a semiconductor storage device during assembly with the routing tabs removed and thermally conductive traces exposed at edges of the depaneled printed circuit board.

FIG. 14 is perspective view of a bottom portion of an enclosure including a side-mounted thermal interface material according to embodiments of the present technology.

FIG. 15 is an edge view of a bottom portion of an enclosure including a side-mounted thermal interface material according to embodiments of the present technology.

FIG. 16 is perspective view of a bottom portion of an enclosure including a side-mounted thermal interface material according to alternative embodiments of the present technology.

FIG. 17 is an edge view of a semiconductor storage device mounted in the bottom portion of an enclosure.

FIG. 18 is an edge view of a completed semiconductor storage device mounted in the top and bottom portions of an enclosure.

FIG. 19 is a perspective view of a completed semiconductor storage device according to embodiments of the present technology.

FIG. 20 is a cross-sectional edge view through line 20-20 of FIG. 19 showing heat dissipation though side portions of the enclosure according to embodiments of the present technology.

FIGS. 21-23 are cross-sectional edge views of completed semiconductor storage devices according to alternative embodiments of the present technology.

### DETAILED DESCRIPTION

The present technology will now be described with reference to the figures, which in embodiments, relate to a semiconductor storage device including semiconductor packages mounted on a printed circuit board (PCB) and encased within an enclosure. The semiconductor storage device includes thermal interface material mounted on side edges of the PCB. During depaneling (separation) of individual semiconductor storage devices from a PCB panel, edges of the PCB may be overcut to expose thermally conductive edge layers provided within the interior the PCB. Once mounted in the enclosure, the thermal interface material may be positioned adjacent to the exposed thermally conductive edge layers to conduct heat away from a semiconductor package during operation, through the side edges of the PCB and out of sides of the enclosure.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

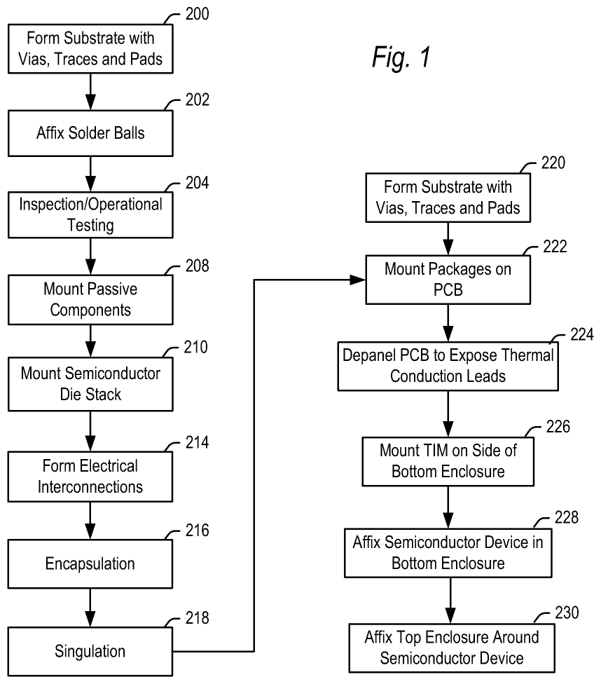

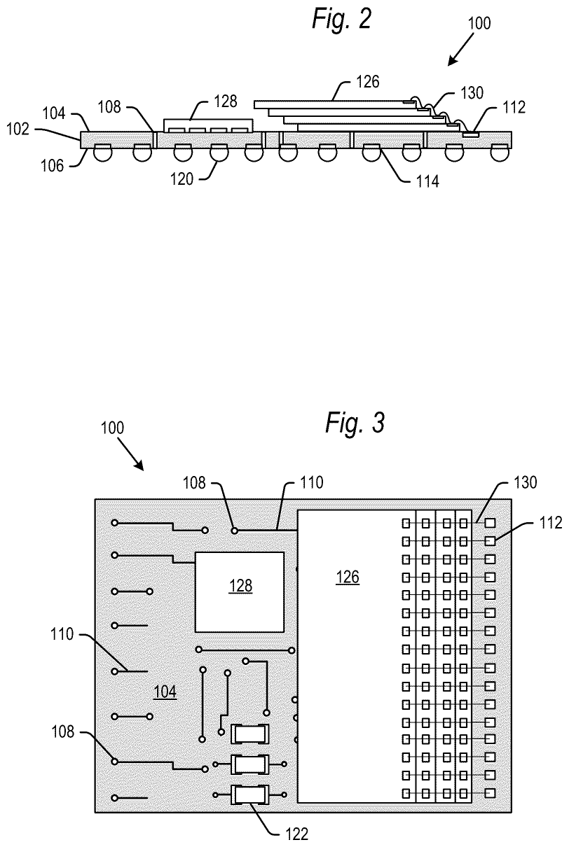

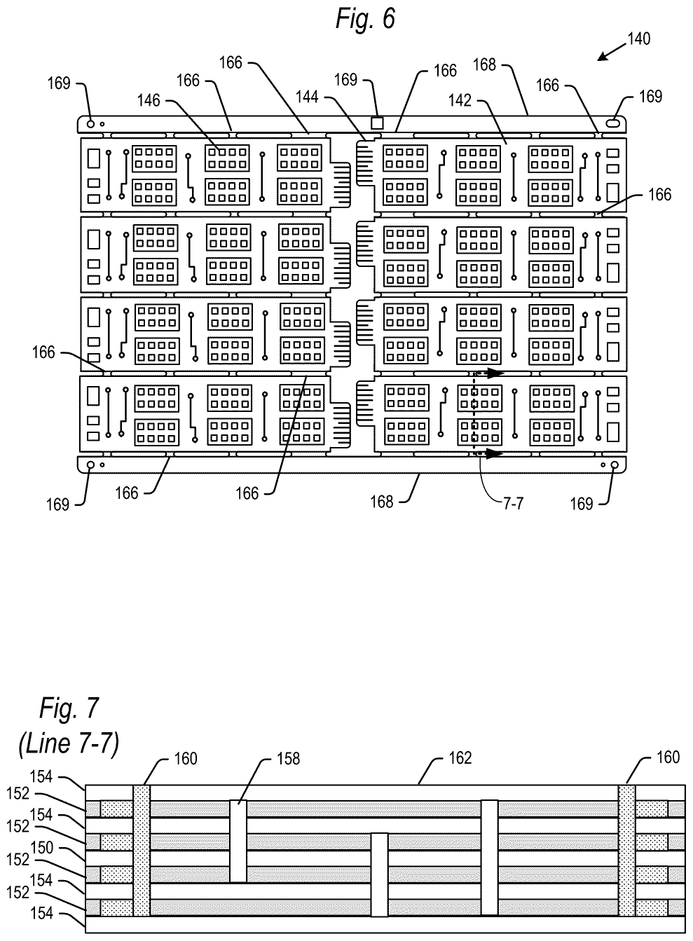

An embodiment of the present technology will now be explained with reference to the flowchart of FIG. 1 and the edge, top and perspective views of FIGS. 2 through 23. FIGS. 2-5 show a semiconductor package 100, or portions thereof, and FIGS. 6-23 show a semiconductor storage device 180, or portions thereof, including semiconductor packages 100. Referring now to FIG. 1 and the edge and top views of FIGS. 2 and 3, there is shown a substrate 102, which as used herein, refers to a signal-carrier medium provided for transferring electrical signals between semiconductor dies mounted on the substrate and a PCB, as explained below. In one embodiment of the present technology, the substrate 102 may be a rigid signal carrier medium, but the substrate 102 may be formed of other signal-carrier mediums such as flex tapes, interposers or combinations thereof.

The substrate 102 is formed in step 200 to include conductive layers on at least a first (e.g., top) major surface 104 and a second (e.g., bottom) major surface 106. The first and second major surfaces 104, 106 may be separated by a dielectric core. There may be additional conductive layers additional dielectric cores in further embodiments. Electrically conductive vias 108 may be formed through the dielectric core between the first and second major surfaces 104, 106, and the conductive layers may be etched in a photolithographic process to define electrical traces 110 and contact pads 112 and 114.

As shown in FIG. 2, the contact pads 112 are provided on the first major surface 104 for electrically bonding semiconductor dies to the substrate 102 as explained below, and the contact pads 114 are provided on the second major surface 106 to physically and electrically attach solder balls to the substrate 102 as explained below. The vias 108 and electrical traces 110 are used to route electrical signals along and between the first and second major surfaces 104, 106. The patterns of vias 108, traces 110 and contact pads 112, 114 shown in the figures is for illustrative purposes only and may vary in further embodiments. The figures show a single substrate 102, but it is understood that the semiconductor package of the present technology may be assembled from a panel of substrates to achieve economies of scale.

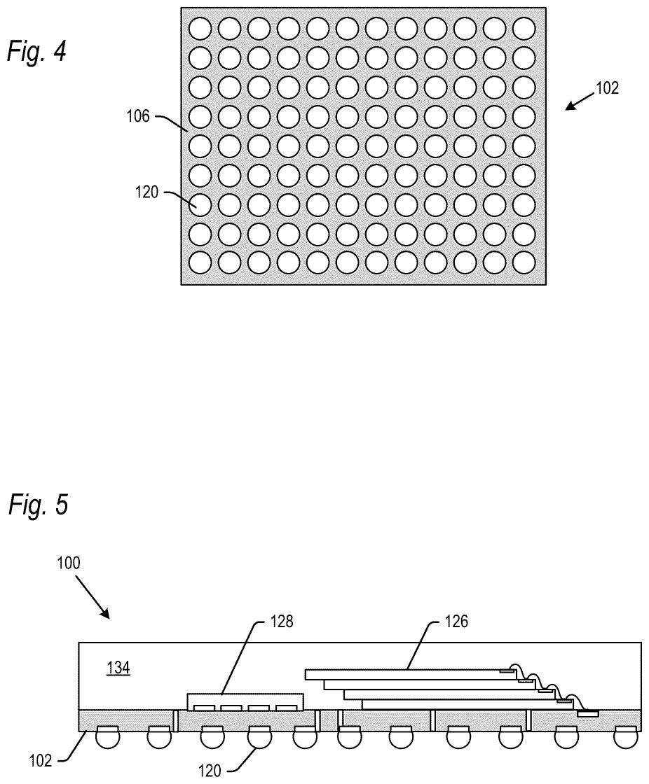

Referring again to FIG. 1, solder balls 120 may be affixed in step 202 to the contact pads 114 on the second major surface 106 of substrate 102 as shown in FIGS. 2 and 4. The balls 120 may be solder, but may also be formed of copper, aluminum tin, gold, alloys thereof, or other flowable metals and materials in further embodiments. FIG. 4 shows a high concentration of solder balls 120, but the solder balls 120 may be applied in a variety of different patterns in further embodiments.

The completed substrate 102 may be inspected and operationally tested in step 204. These inspections may for example include an automatic optical inspection (AOI), an automated visual inspection (AVI) and/or a final visual inspection (FVI) to check for defects, contamination, scratches and discoloration. One or more of these steps may be omitted or performed in a different order in further embodiments. Assuming the substrate 102 passes inspection, passive components 122 (FIG. 3) may next be affixed to the top surface 104 of the substrate 102 in a step 208. The one or more passive components may include for example one or more capacitors, resistors and/or inductors, though other components are contemplated. The passive components 122 shown are by way of example only, and the number, type and position may vary in further embodiments.

In step 210, one or more semiconductor dies 126, 128 may be mounted on the top surface 104 of the substrate 102. As shown in the edge and top views of FIGS. 2 and 3, the semiconductor dies 126 may for example be one or more memory dies such as 2D NAND flash memory or 3D BiCS (Bit Cost Scaling), V-NAND or other 3D flash memory, but other types of dies 126 may be used. These other types of semiconductor dies include but are not limited to RAM such as an SDRAM, DDR SDRAM, LPDDR and GDDR.

Where multiple semiconductor dies 126 are included, the semiconductor dies 126 may be stacked atop each other in an offset stepped configuration to form a die stack as shown in FIGS. 2 and 3. The number of dies 126 shown in the stack is by way of example only, and embodiments may include different numbers of semiconductor dies, including for example 1, 2, 4, 8, 16, 32 or 64 dies. There may be other numbers of dies in further embodiments. The dies may be affixed to the substrate and/or each other using a die attach film. As one example, the die attach film may be cured to a B-stage to preliminarily affix the dies 126 in the stack, and subsequently cured to a final C-stage to permanently affix the dies 126 to the substrate 102.

FIGS. 2 and 3 also show a semiconductor die 128 which may for example be a controller die surface mounted to the substrate 102. Controller die 128 may for example be an ASIC for controlling transfer of signals and data to and from the memory dies 126. The controller die 128 may be flip-chip mounted to contact pads 118 by solder or Cu-to-Cu bonding. The controller die 128 may alternatively be electrically coupled to substrate 102 with bond wires as explained in the following paragraph.

In step 214, the semiconductor memory dies 126 may be electrically interconnected to each other and to the contact pads 112 of the substrate 102. FIGS. 2 and 3 show bond wires 130 formed between corresponding (like channel) die bond pads on respective dies 126 down the stack, and then bonded to contact pads 112 on the substrate 102. The bond wires 130 may be formed by a ball-bonding technique, but other wire bonding techniques are possible. The semiconductor dies 126 may be electrically interconnected to each other and the substrate 102 by other methods in further embodiments, including by through-silicon vias (TSVs) and flip-chip technologies. As noted, when not surface mounted, the controller die 128 may also be wire bonded to the substrate in step 214.

Following electrical connection of the dies 126, 128 to the substrate 102, the semiconductor package 100 may undergo an encapsulation process in step 216. As shown in the edge view of FIG. 5, a mold compound 134 may be applied over the components on the top surface 104 at the substrate 102 to encapsulate and protect the passive components 122 and the semiconductor dies 126, 128. Mold compound 134 may include for example solid epoxy resin, Phenol resin, fused silica, crystalline silica, carbon black and/or metal hydroxide. Other mold compounds from other manufacturers are contemplated. The mold compound may be applied by various known processes, including by FFT (flow free thin) molding, compression molding, transfer molding or injection molding techniques.

At this stage in the assembly, the individual semiconductor packages 100 may still be part of a substrate panel. After the semiconductor packages 100 are encapsulated, they may be singulated from the panel in step 218 to form the completed semiconductor packages 100 as shown for example in the edge view of FIG. 5. The individual semiconductor packages 100 may be singulated from the panel using any of a variety of cutting methods including by saw blade, laser, waterjet or other methods.

Once completed, the semiconductor packages 100 may be mounted to printed circuit boards in step 220 using solder balls 120. FIG. 6 is a top view of a sample PCB panel 140 including a number of PCBs 142 according to embodiments of the present technology. FIG. 7 is a cross-sectional view through line 7-7 of a single PCB 142 showing a sample interior configuration of the PCB 142. FIG. 6 shows a particular configuration of a PCB panel 140 including 8 PCBs 142 in a 2×4 array. However, it is understood that PCB panel 140 may include fewer or greater numbers of PCBs 142, and in different configurations on panel 140, in further embodiments.

The PCB panel 140 of PCBs 142 may be formed in step 220. Each PCB 142 on panel 140 may include an edge connector 144 for connecting the semiconductor storage devices formed on PCBs to a host device as explained below. Each PCB 142 on panel 140 may further include contact pads 146 for receiving solder balls 120 as explained below to physically and electrically couple the semiconductor packages 100 to the PCB 142. The number and position of contact pads 146 is by way of example only and the number and position of contact pads 146 may vary in further embodiments.

Referring now to the cross-sectional edge view of FIG. 7, the PCB 142 may include a dielectric core layer 150, a number of conductive layers 152 and a number of prepreg layers 154. The dielectric core layer 150 may be formed of various dielectric materials such as for example, polyimide laminates, epoxy resins including FR4 and FR5, bismaleimide triazine (BT), and the like. The core 150 may be ceramic or organic in alternative embodiments. The conductive layers 152 may be formed of copper or copper alloys, plated copper or plated copper alloys, Alloy 42 (42Fe/58Ni), copper plated steel, or other metals and materials suitable for use in printed circuit boards. The number of conductive layers 152 are shown by way of example only and there may be more or less conductive layers in further embodiments. The prepreg layers 154 may be formed of a dielectric thermosetting resin to adhere the various layers of the PCB to each other while electrically insulating the conductive layers from each other. The number of prepreg layers 154 are shown by way of example only and there may be more or less prepreg layers in further embodiments. In alternative embodiments, the dielectric core 150 may be omitted and instead replaced by another prepreg layer 154. A solder mask (not shown) may also be provided on the top and/or bottom surfaces of PCB 142.

One or more of the conductive layers 152 may be etched into conductive traces to carry electrical signals to and from the semiconductor packages 100 mounted on a PCB as explained below. Through hole vias 158 may be formed through the layers and plated or filled with conductive material to electrically couple the selected conductive layers 152 to each other. The number and position of the vias 158 are shown by way of example only and may vary in further embodiments.

One or more of the conductive layers 152 may additionally or alternatively have non-signal carrying portions. These conductive layers 152, or portions of conductive layers, may be provided for conducting heat away from the semiconductor packages 100 as explained below. Thermally conductive vias 160, plated or filled with copper or other heat conductor, may be provided through the conductive layers 152 to conduct heat between and into the layers 152. In embodiments, the thermally conductive vias 160 may extend to a first (e.g., upper) surface 162 of the PCB 142, or may extend up into contact with a contact pad 146 on the surface 162 of the PCB 142.

Referring again to FIG. 6, the individual PCBs 142 may be held to each other within panel 140 by tabs 166. The panel 140 may also include borders 168 at first and second opposed edges of the panel 140. The borders 168 may include fiducial marks 169 used to align and identify the position of the panel 140 in various tools, for example those used to affix the semiconductor packages 100 to the PCBs 142 as explained below. In addition to affixing the PCBs 142 to each other, the tabs 166 may also be used to affix the borders 168 to the panel 140.

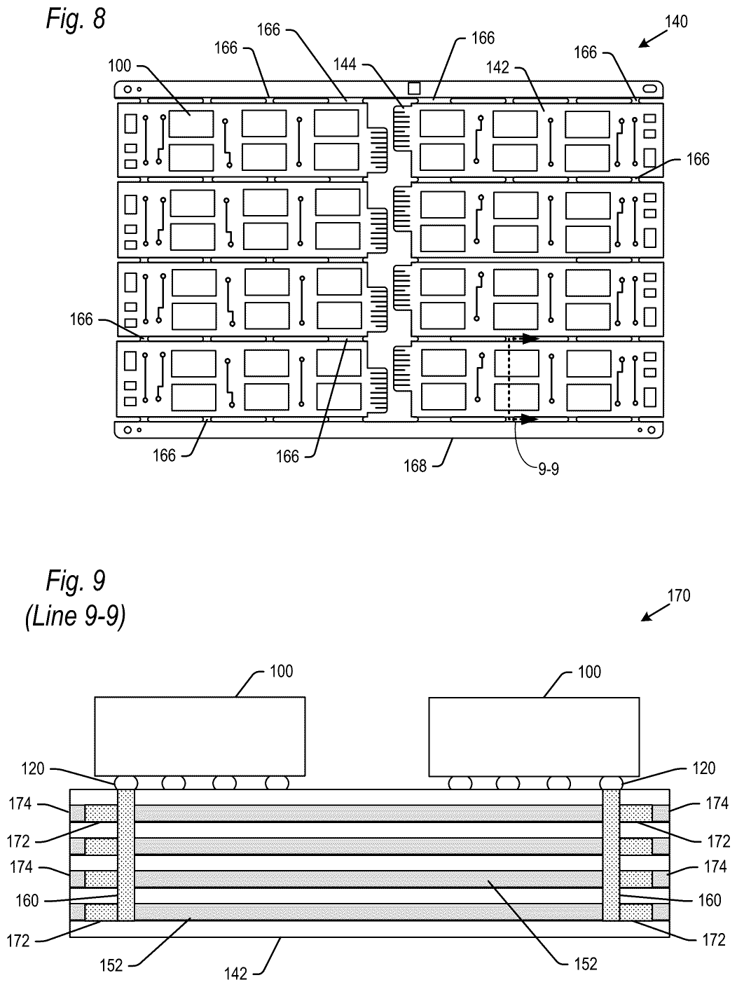

In step 222, the semiconductor packages 100 may be mounted on PCBs 142. FIG. 8 is a top view of panel 140 showing semiconductor packages 100 mounted on PCBs 142. FIG. 9 is a cross-sectional view through line 9-9 of FIG. 8, across a width of a PCB 142, showing a pair of semiconductor package 100 mounted on the PCB 142. The embodiment of FIG. 8 shows six semiconductor packages 100 mounted on each PCB 142. However, there may be more or less semiconductor packages 100 on each PCB 142 in further embodiments. As noted above, the semiconductor packages 100 are mounted on PCB 142 by solder balls 120 mating with contact pads 146 on PCB 142. The embodiment of FIG. 9 shows two of the solder balls 120 (the two outermost solder balls 120) mounted on top of thermally conductive via 160. There may be multiple solder balls 120 in the two outermost rows of solder balls 120 (into the page of FIG. 9) mounted on top of thermally conductive vias 160. Alternatively, solder balls in other rows may additionally or alternatively be mounted on top of thermally conductive vias 160.

As noted above, some of the conductive layers 152, or portions of the conductive layers 152, in PCB 142 may be provided for conduction of heat away from semiconductor packages 100. FIG. 9 shows thermally conductive edge layers 172 in each of the conductive layers 152. The thermally conductive edge layers 172 may be traces etched in the conductive layers 152, or solid regions in the conductive layers 152, that extend from the thermally conductive vias 160 out towards edges of the PCB 142. At this stage in the assembly, the thermally conductive edge layers 172 do not extend to the edges of the PCB 142. In particular, at this stage in the assembly, the outer edges of the conductive layers 160 are protected by dielectric edge portions 174. Dielectric edge portions 174 may for example be any of various dielectric materials such as for example, polyimide laminates, epoxy resins and the like. The purpose of dielectric edge portions 174 is to prevent exposure of the thermally conductive edge layers 172 to the air, which may otherwise result in an oxidation layer forming on the exposed areas of the thermally conductive edge layers 172.

The PCB 142 may also be referred to herein as a signal carrier medium, in that the PCB 142 carries signals to and from the semiconductor packages 100. Other types of signal carrier mediums may be used instead of PCB 142, including for example flex tapes, interposers and substrates. Each of these signal carrier mediums may be configured with a number of electrically and thermally conductive layers, interspersed with dielectric layers, where at least some of the thermally conductive layers may be used for the thermally conductive edge layers.

The PCB 142 may also be referred to herein as a head conduction medium, in that the PCB 142 carries heat away from the semiconductor packages 100. In embodiments, the heat conduction portions of PCB 142 (thermally conductive vias 160 and edge layers 172) may be isolated on PCB 142 from the signal carrying portions of the PCB 142. It is conceivable that the heat conduction portions may be placed on an entirely different medium than the signal carrying portions (so there are in effect multiple, separate PCBs in each semiconductor storage device 180). As used herein, a heat conduction medium may at least conduct heat away from the semiconductor packages 100, and may optionally carry signals to and from the semiconductor packages 100.

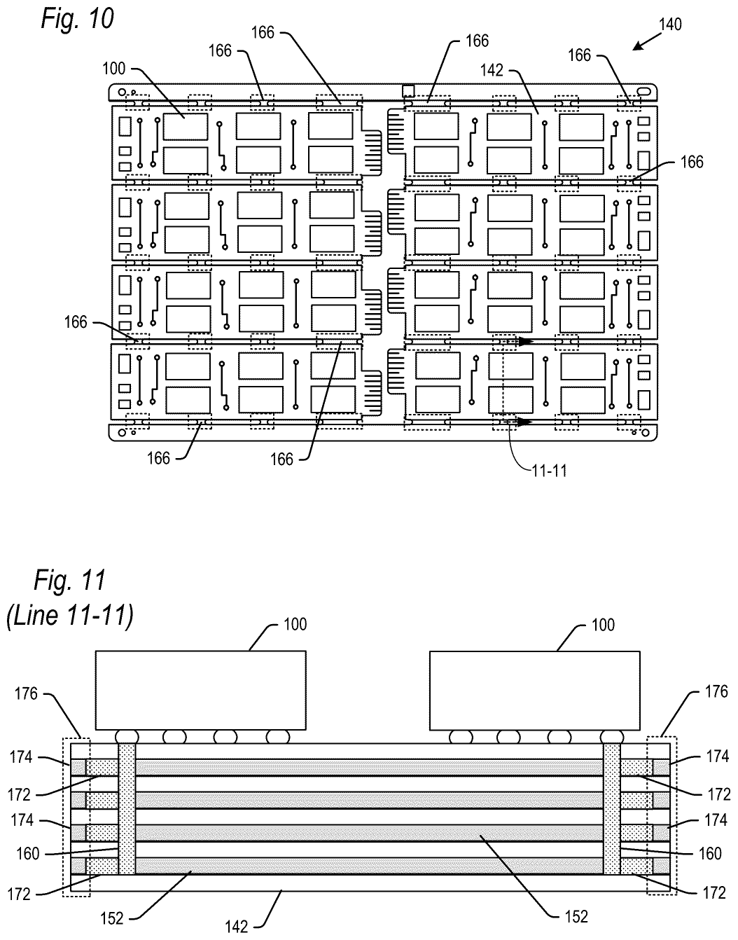

At this stage in the assembly, each of the PCBs 142 are held in panel 140 by tabs 166. FIG. 10 is a top view of a panel 140 showing dashed boxes around tabs 166. FIG. 11 is a cross-sectional view through line 11-11 of FIG. 10. FIG. 11 shows the pair of semiconductor packages 100 discussed above, as well as the thermally conductive vias 160, thermally conductive edge layers 172 and dielectric edge portions 174. FIG. 11 further shows dashed boxes around vertical edge regions 176 at edges of the PCB 142 including the dielectric edge portions 174 in each of the conductive layers 152.

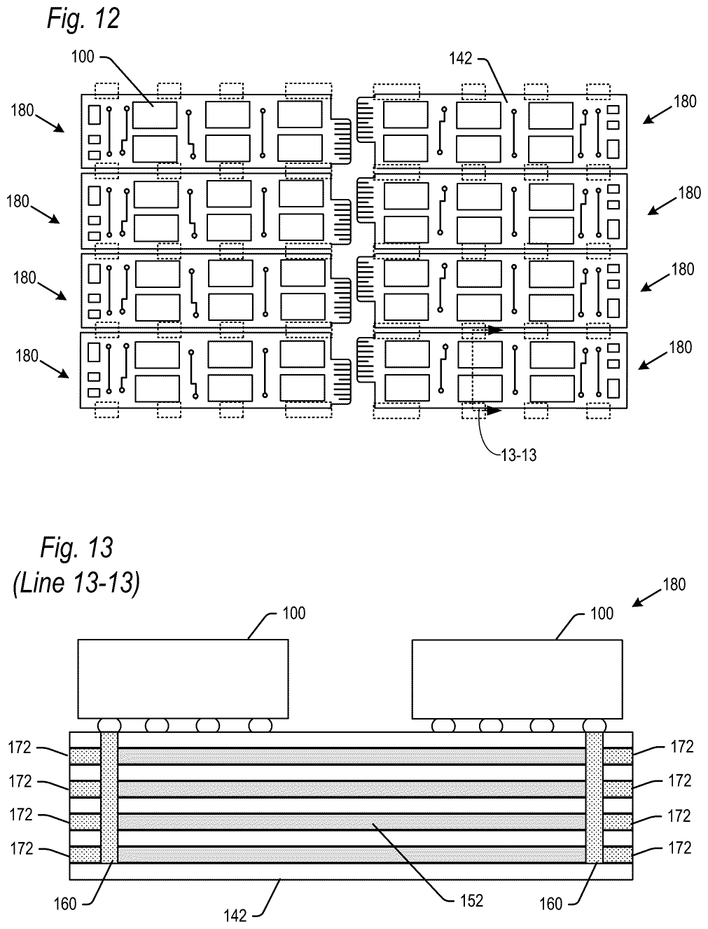

In step 224, the individual PCBs 142 may be depaneled (separated) from the panel 140 by removing tabs 166 to form individual semiconductor storage devices 180 as shown in the top view of FIG. 12. The tabs 166 may be removed by drill, saw or other cutting method. In accordance with aspects of the present technology, the edges of the PCBs 142 may be overcut. That is, instead of merely removing the tabs 166, more of the edges of the PCBs 142 are removed. FIG. 13 is a cross-sectional edge view of a semiconductor storage device 180 through line 13-13 of FIG. 12. FIG. 13 shows that vertical edge regions 176 have been removed by the overcut during depaneling step 224. After the depaneling step, the thermally conductive edge layers 172 are exposed at the edges of the PCB 142. In embodiments, the overcut may take place only at the tabs 166 (only in the areas of the dashed boxes in FIG. 12). In further embodiments, the overcut may take place along the entire top and bottom edges of each PCB 142 in panel 140.

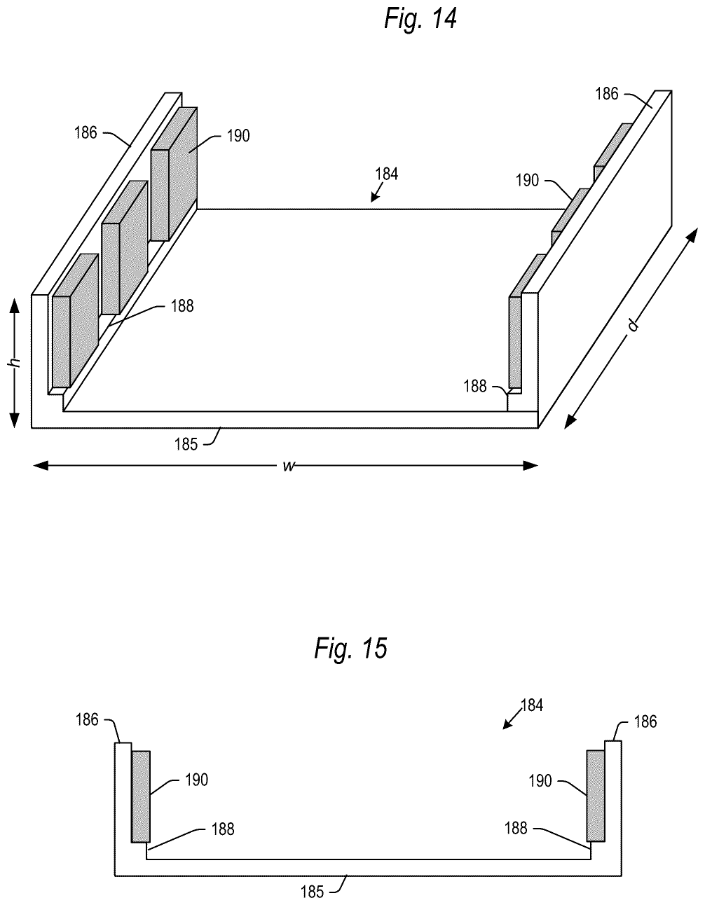

After completion of the semiconductor storage device 180 as shown in FIGS. 12 and 13, the semiconductor storage device 180 may be mounted within an enclosure in steps 226-230. FIGS. 14 and 15 show perspective and edge views of a bottom enclosure 184. The bottom enclosure 184 may be formed of a conductive material such as aluminum or alloys thereof, and may be formed for example by extrusion or casting, though other methods may be used. The bottom enclosure 184 may have a base 185 and upwardly extending sidewalls 186 on opposed edges of the base 185. The thickness of the base and sidewalls 185, 186 may each be 0.5 mm to 1.5 mm, though they may be thicker or thinner than that in further embodiments. A shoulder 188 may be formed where the base 185 and sidewalls 186 come together. The shoulder may be omitted in further embodiments. The bottom enclosure may have a width, w, slightly greater than a width of the PCB 142, a depth, d, slightly greater than or equal to a length of the PCB 142, and a height, h, slightly greater than a thickness of the PCB 142. The figures, including FIGS. 14 and 15, are conceptual and not drawn to scale.

Thermal interface materials (TIMs) 190 may be mounted within the bottom enclosure 184 on shoulders 188 (or simply on an inner surface of sidewalls 186 where shoulders 188 are omitted). TIMs 190 may be formed of a thermally conductive material such as copper, aluminum, alloys of copper and/or aluminum, graphite and other materials. Each TIM 190 may have a thickness of 0.5 mm to 2 mm, though the thickness of TIMs 190 may be less than or greater than that in further embodiments. Each TIM 190 may have a height about equal to a thickness of the PCB 142.

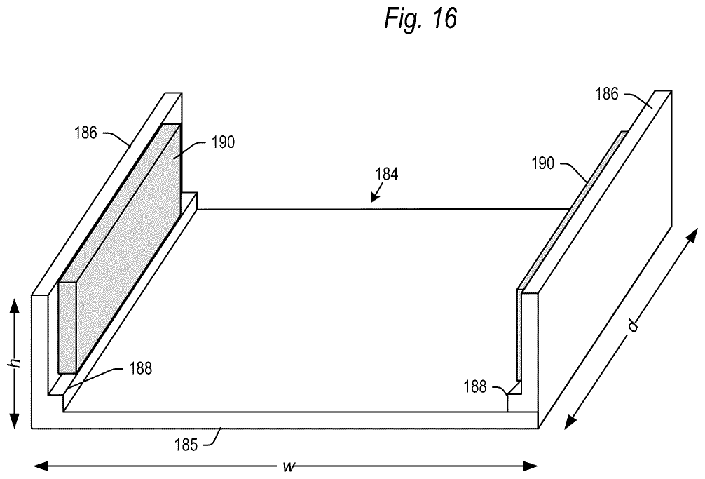

In embodiments described above, the PCB 142 is overcut at tabs 166 during the depaneling step 224. Such an embodiment creates notches in the areas where the overcuts are made. For such embodiments, each sidewall 186 may have a number of TIMs 190 as shown in FIG. 14 that correspond in size and position to the notches formed during the overcut of depaneling step 224. Thus, when the semiconductor storage device 180 is inserted into the bottom enclosure 184 as described below, the TIMs 190 fit within the notches. In further embodiments described above, the entire top and bottom edges are overcut during the depaneling step 224. For such embodiments, each sidewall 186 may have a single TIM 190 as shown in FIG. 16 that extends the full depth, d, of the bottom enclosure 184.

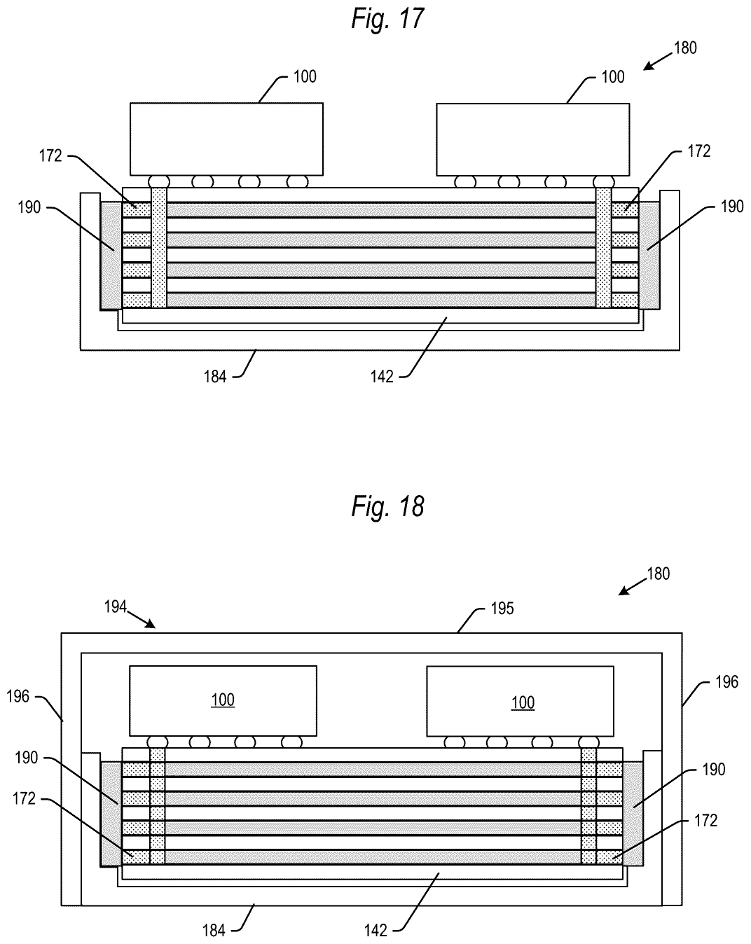

In step 228, a semiconductor storage device 180 may be mounted in the bottom enclosure 186 as shown in the cross-sectional view of FIG. 17. In accordance with aspects of the present technology, when the device 180 is mounted within bottom enclosure 186, the thermally conductive edge layers 172 lie adjacent to the TIMs 190 on both sidewalls 186. In embodiments, the TIMs 190 lie in direct contact with the thermally conductive edge layers 172. In further embodiments, there may be a small space between the TIMs 190 and the thermally conductive edge layers 172. In such embodiments, the space may be filled with a thermally conductive epoxy or other sealant. Even where the TIMs 190 lie in direct contact with the thermally conductive edge layers 172, an epoxy or other sealant may be poured or injected between the edge of PCB 142 and the TIMs 190 and/or sidewalls 186 to prevent oxidation of any portions of the edge layers 172, or conductive layers 152 in general, exposed at an edge of the PCB 142. In further embodiments, silicone-based TIM may be used to allow a degree of oil greasing effect to cover thermally conductive edge layers to prevent oxidation of any portions of the edge layers. The semiconductor storage device 180 may be mounted within the bottom enclosure 184 by various fasteners, including by an adhesive or set screws.

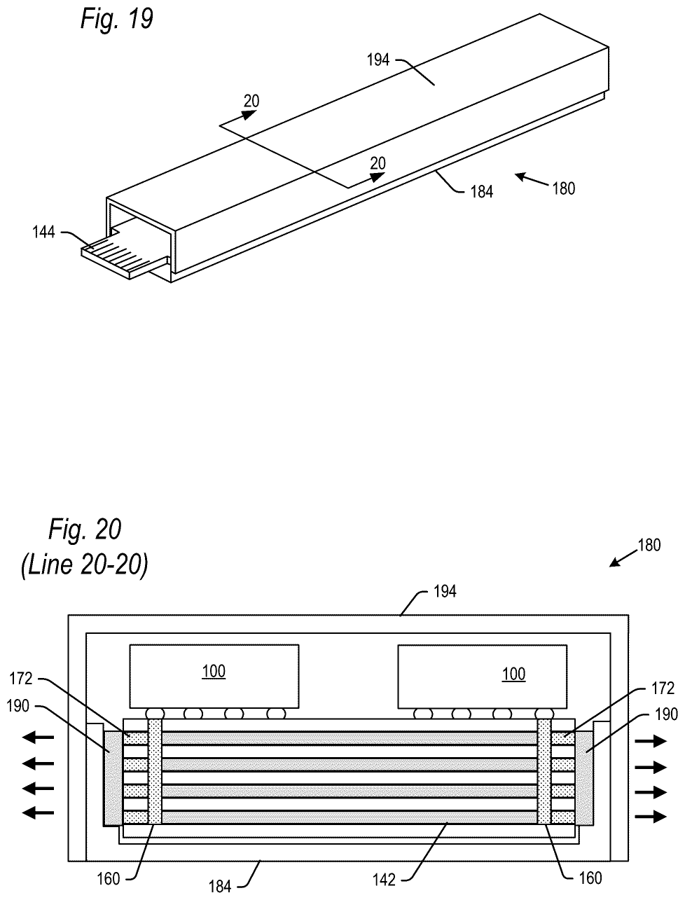

In step 230, a top enclosure 194 may be affixed over the bottom enclosure 184 as shown in the cross-sectional view of FIG. 18 and the perspective view of FIG. 19. The top enclosure includes top 195 and downwardly extending sidewalls 196 on opposed edges of the top 195. The thickness of the top and sidewalls 195, 196 may each be 0.5 mm to 1.5 mm, though they may be thicker or thinner than that in further embodiments. The sidewalls 196 and the top enclosure are sized and configured to fit down snugly over the sidewalls 186 of the bottom enclosure to enclose the semiconductor storage device 180 therein. The top enclosure 194 may be affixed to the bottom enclosure 194 by various fasteners, including for example by a lip or clasp on one or both of the top and bottom enclosures 184, 194. In further embodiments, assembly steps 226 to step 230 may be revised to mount TIM on side of top enclosure, affix semiconductor device in top enclosure and then affix bottom enclosure around semiconductor device based on design requirements.

As shown in FIG. 19, once the enclosure is assembled, the edge connector 144 may protrude from the enclosure to enable connection of the semiconductor storage device 180 to a host device. This host device may for example include a motherboard of a computer, or a host device slot, for removably receiving the semiconductor storage device 180.

The top and bottom enclosures 184, 194 provide a number of features, including protection of the semiconductor storage device 180, electrostatic discharge and dissipation of heat generated by the semiconductor storage device 180 as described herein. In embodiments, the enclosure is comprised of separate top and bottom enclosures 184, 194. However, in further embodiments, the top and bottom portions of the enclosure may be integrally formed with each other. In such embodiments, a semiconductor storage device 180 may be inserted into the enclosure through an open end of the enclosure.

The top and bottom enclosures 184, 194 together define a standard form factor for current commercial semiconductor storage devices. Use of certain types of memory packages 100, such as those including 3D NAND, do not leave room on top of these memory devices for inclusion of a TIM. Therefore, in accordance with aspects of the present technology, the TIM(s) are provided at one or more edges of the PCB 142. Referring to FIG. 20, there is shown a semiconductor storage device 180 including semiconductor packages 100 that generate heat during read/write and other operations. Heat is dissipated from semiconductor packages 100 through a pathway including one or more of the solder balls 120 connected to thermally conductive via(s) 160, from the via(s) 160 to the thermally conductive edge layers 172, from edge layers 172 to the TIM(s) 190, and from the TIM(s) 190 out through the sidewalls of the top and bottom enclosures 184, 194. Thus, the present technology provides a thermal conduction pathway through the edges of the PCB 142, thereby omitting the need for a TIM on a top surface of package 100.

As noted, the number of thermally conductive edge layers 172 may vary, and the overall thickness of PCB 142 may vary, in different embodiments of the present technology. In embodiments, the height of the TIMs 190 may vary to allow contact between the TIMs and each of the thermally conductive edge layers 172. However, in further embodiments, the TIMs may have a height such that they do not cover each of the thermally conductive edge layers 172.

Moreover, in the embodiments shown, the thermally conductive via 160 is aligned with the outermost rows of solder balls 120. In further embodiments, there may be one or more thermally conductive vias 160 positioned beneath solder balls 120 that are located closer to the center of semiconductor package 100. In such embodiments, the thermally conductive edge layers would extend through the PCB 142 into contact with these thermally conductive vias to conduct heat away from the one or more semiconductor packages as described above.

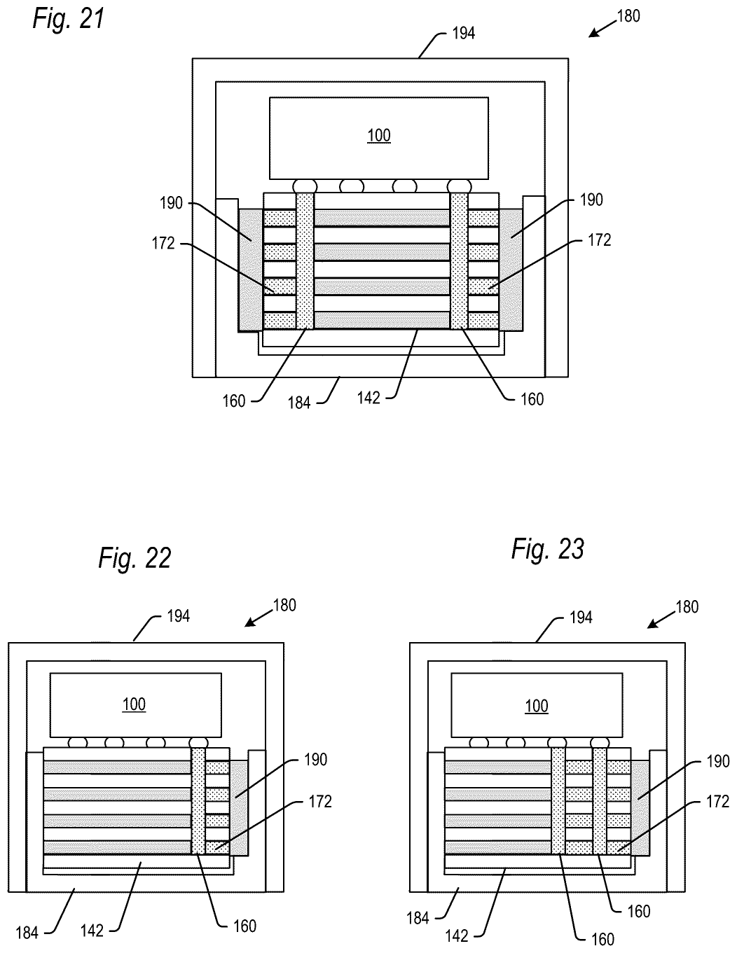

In certain embodiments described above, the semiconductor device 180 includes two rows of semiconductor packages 100, as shown for example in the top views of FIGS. 8 and 12, and into the page of FIGS. 18 and 20. As noted, the number of semiconductor packages 100 in a row may vary in further embodiments of the present technology. Moreover, instead of two rows, there may be a single row of semiconductor packages 100 across a width of PCB 142 as shown for example in FIGS. 21-23.

In FIG. 21, there is shown a cross-sectional edge view of a semiconductor storage device 180 including a single row of one or more semiconductor packages 100 (into the page of FIG. 21). In this embodiment, solder balls 120 in two rows of solder balls on a semiconductor package 100 connect with two thermally conductive vias 160. Heat is then conducted from vias 160, toward opposed sides of the PCB 152, out of the enclosure through edge layers 172 and TIMs 190 as described above.

FIG. 22 is similar to FIG. 21, including a single row of one or more semiconductor packages 100. However, in this embodiment, there is a TIM 190 on only one edge of the device 180, and there is a single set of thermally conductive via(s) 160 and thermally conductive edge layers 172 conducting heat to this TIM 190.

FIG. 23 is similar to FIG. 22, except that FIG. 23 includes two rows (into the page) of thermally conductive vias 160 conducting heat to thermally conductive edge layers 172 off of one edge of PCB 142. Any of the above-described embodiments may include more than one row of thermally conductive vias 160 conducting heat away through an edge of the PCB 142.

In summary, in one example, the present technology relates to a semiconductor storage device, comprising: a heat conduction medium, comprising: one or more thermally conductive layers extending to an edge of the heat conduction medium; one or more thermally conductive vias configured to conduct heat to the one or more thermally conductive layers; a semiconductor package mounted on a surface of the heat conduction medium by a plurality of solder balls, wherein the one or more thermally conductive vias are positioned adjacent to a group of one or more solder balls of the plurality of solder balls to conduct heat from the semiconductor package through the one or more solder balls; and a thermal interface material (TIM) mounted adjacent to the edge of the heat conduction medium, the one or more thermally conductive layers configured to conduct heat to the TIM.

In a further example, the present technology relates to a semiconductor storage device, comprising: a printed circuit board (PCB), comprising: one or more thermally conductive layers exposed at an edge of the PCB; one or more thermally conductive vias configured to conduct heat to the one or more thermally conductive layers; a semiconductor package mounted on a surface of the PCB by a plurality of solder balls, wherein the one or more thermally conductive vias are positioned adjacent to a group of one or more solder balls of the plurality of solder balls; and a thermal interface material (TIM) mounted at the edge of the PCB in contact with the one or more thermally conductive layers; wherein a thermal conduction path exists to conduct heat away from the semiconductor package through the edge of the PCB, the thermal conduction path comprising the one or more solder balls, the one or more thermally conductive vias, the one or more thermally conductive layers and the TIM.

In another example, the present technology relates to a semiconductor storge device, comprising: a pliable printed circuit board comprising a first major surface and a second major surface opposed to the first major surface, wherein the pliable printed circuit board is configured to flex; a first plurality of semiconductor packages, each semiconductor package of the first plurality of semiconductor packages comprising a first group of solder balls, the first group of solder balls affixing the first plurality of semiconductor packages to the first major surface of the pliable printed circuit board at least along a first direction; and a second plurality of semiconductor packages, each semiconductor package of the second plurality of semiconductor packages comprising a second group of solder balls, the second group of solder balls affixing the second plurality of semiconductor packages to the second major surface of the printed circuit board at least along the first direction; wherein the first plurality of semiconductor packages on the first major surface is staggered with an overlap relative to the second plurality of semiconductor packages on the second major surface along the first direction, and wherein the staggering allows flexing of the pliable printed circuit board upon warping of one or more of the first and second pluralities of semiconductor packages to maintain stain energy densities in the first and second groups of solder balls below a predefined threshold.

In a further example, the present technology relates to a semiconductor storage device, comprising: a printed circuit board (PCB), the PCB having a surface and an edge adjacent to the surface; a semiconductor package mounted on the surface of the PCB by a plurality of solder balls; an enclosure enclosing the PCB and semiconductor package; first means for conducting heat from the semiconductor package, through the plurality of solder balls, to the edge of the PCB; and second means for conducting heat away from the edge of the PCB to the enclosure.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A semiconductor storage device, comprising:
a heat conduction medium, comprising:
one or more thermally conductive layers extending to an edge of the heat conduction medium;
one or more thermally conductive vias configured to conduct heat to the one or more thermally conductive layers;
a semiconductor package mounted on a surface of the heat conduction medium by a plurality of solder balls, wherein the one or more thermally conductive vias are positioned adjacent to a group of one or more solder balls of the plurality of solder balls to conduct heat from the semiconductor package through the one or more solder balls; and
a thermal interface material (TIM) mounted adjacent to the edge of the heat conduction medium, the one or more thermally conductive layers configured to conduct heat to the TIM.

2. The semiconductor storage device of claim 1, further comprising an enclosure including a sidewall, the TIM configured to conduct heat to the sidewall of the enclosure.

3. The semiconductor storage device of claim 1, wherein the TIM is in direct contact with the one or more thermally conductive layers at the edge of the heat conduction medium.

4. The semiconductor storage device of claim 1, wherein the TIM is spaced from the one or more thermally conductive layers at the edge of the heat conduction medium.

5. The semiconductor storage device of claim 4, further comprising an electrically conductive epoxy in a space between the TIM and the one or more thermally conductive layers

6. The semiconductor storage device of claim 1, the TIM is one of a plurality of TIMs along the edge of the heat conduction medium.

7. The semiconductor storage device of claim 1, wherein the one or more thermally conductive layers comprise a first set of thermally conductive layers, the edge comprises a first edge and the one or more thermally conductive vias comprise a first set of thermally conductive vias, the heat conduction medium further comprising:
a second set of one or more thermally conductive layers extending to a second edge of the heat conduction medium, and
a second set of one or more thermally conductive vias configured to conduct heat to the second set of one or more thermally conductive layers.

8. The semiconductor storage device of claim 7, wherein the TIM comprises a first TIM, the semiconductor storage device further comprising a second thermal interface material (TIM) mounted adjacent to the second edge of the heat conduction medium, the second set of one or more thermally conductive layers configured to conduct heat to the second TIM.

9. The semiconductor storage device of claim 7, wherein the group of one or more solder balls of the semiconductor package comprise a first group of one or more solder balls, and wherein the second set of one or more thermally conductive vias are configured to receive heat from a second group of one or more solder balls of the plurality of solder balls.

10. The semiconductor storage device of claim 7, further comprising a second semiconductor package mounted on the surface of the heat conduction medium, the second semiconductor package comprising a second plurality of solder balls.

11. The semiconductor storage device of claim 10, wherein the first semiconductor package is positioned adjacent to the first edge and the second semiconductor package is positioned adjacent to the second edge, and wherein the second group of one or more thermally conductive vias are positioned adjacent to a second group of one or more solder balls of the second plurality of solder balls to conduct heat from the second semiconductor package through the second group of one or more solder balls to the second set of one or more thermally vias.

12. The semiconductor storage device of claim 10, wherein the first and semiconductor packages are positioned adjacent to the first edge, and wherein the first group of one or more thermally conductive vias are positioned adjacent to a second group of one or more solder balls of the second plurality of solder balls to conduct heat from the second semiconductor package through the second group of one or more solder balls to the first group of one or more thermally conductive vias.

13. The semiconductor storage device of claim 1, wherein the heat conduction medium comprises a printed circuit board comprising the one or more thermally conductive layers interspersed with one or more dielectric layers.

14. A semiconductor storage device, comprising:
a printed circuit board (PCB), comprising:
one or more thermally conductive layers exposed at an edge of the PCB;
one or more thermally conductive vias configured to conduct heat to the one or more thermally conductive layers;
a semiconductor package mounted on a surface of the PCB by a plurality of solder balls, wherein the one or more thermally conductive vias are positioned adjacent to a group of one or more solder balls of the plurality of solder balls; and
a thermal interface material (TIM) mounted at the edge of the PCB in contact with the one or more thermally conductive layers;
wherein a thermal conduction path exists to conduct heat away from the semiconductor package through the edge of the PCB, the thermal conduction path comprising the one or more solder balls, the one or more thermally conductive vias, the one or more thermally conductive layers and the TIM.

15. The semiconductor storage device of claim 14, wherein the PCB comprises one or more notches along the edge, wherein the one or more thermally conductive layers are positioned at least partially in the one or more notches, and wherein the TIM is positioned in the one or more notches.

16. The semiconductor storage device of claim 15, wherein the one or more notches correspond in position to one or more tabs removed from the PCB during a depaneling step.

17. The semiconductor storage device of claim 15, wherein the one or more thermally conductive layers at the notches on the PCB edge are exposed after depaneling.

18. The semiconductor storage device of claim 14, further comprising an enclosure including a sidewall, the TIM configured to conduct heat to the sidewall of the enclosure.

19. The semiconductor storage device of claim 14, wherein the TIM is in direct contact with the one or more thermally conductive layers at the edge of the heat conduction medium.

20. A semiconductor storage device, comprising:
a printed circuit board (PCB), the PCB having a surface and an edge adjacent to the surface;
a semiconductor package mounted on the surface of the PCB by a plurality of solder balls;
an enclosure enclosing the PCB and semiconductor package;
first means for conducting heat from the semiconductor package, through the plurality of solder balls, to the edge of the PCB; and
second means for conducting heat away from the edge of the PCB to the enclosure.
